(19) United States
(12) Patent Application Publication
(10) Pub. No.: US 2007/0023825 A1
(43) Pub. Date: Feb. 1, 2007

(54) Semiconductor device

(75) Inventor: Akinori Shindo, Hokuto (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/478,486

(22) Filed: Jun. 29, 2006

(30) Foreign Application Priority Data
Jul. 28, 2005 (JP) 2005-218904

(51) Int. Cl. H01L 29/76

(52) U.S. Cl. 257/327

(57) ABSTRACT

A semiconductor device having: a semiconductor layer; an interlayer dielectric formed on the semiconductor layer; a buffer layer formed on the interlayer dielectric; and an electrode pad formed on the interlayer dielectric, the buffer layer being formed to be covered by an edge portion of at least part of the electrode pad when viewed from a top side.

Japanese Patent Application No. 2005-218904, filed on Jul. 28, 2005, is hereby incorporated by reference in its entirety.

### BACKGROUND OF THE INVENTION

The present invention relates to a semiconductor device.

When a semiconductor element such as a MIS transistor is disposed under a pad, the characteristics of the semiconductor element may be impaired due to stress during bonding. Therefore, a pad formation region and a semiconductor element formation region are separately provided in a semiconductor chip when viewed from the top side. In recent years, along with a reduction in size and an increase in degree of integration of a semiconductor chip, disposition of a semiconductor element under a pad has been demanded. JP-A-11-307724 discloses an example of such a technology. JP-A-11-307724 discloses an island-like buffer layer formed under a bonding pad.

### SUMMARY

According to one aspect of the invention, there is provided a semiconductor device comprising:
a semiconductor layer;
an interlayer dielectric formed on the semiconductor layer;
a buffer layer formed on the interlayer dielectric; and
an electrode pad formed on the interlayer dielectric,
the buffer layer being formed to be covered by an edge portion of at least part of the electrode pad when viewed from a top side.

### BRIEF DESCRIPTION OF THE SEVERAL VIEWS OF THE DRAWING

FIG. 1 is a view illustrative of a semiconductor device according to one embodiment of the invention.

FIG. 2 is a view illustrative of a semiconductor device according to one embodiment of the invention.

FIG. 3 is a view illustrative of a modification of a buffer layer according to one embodiment of the invention.

FIG. 4 is a view illustrative of a modification of a buffer layer according to one embodiment of the invention.

FIG. 5 is a view illustrative of a semiconductor device according to a modification of one embodiment of the invention.

### DETAILED DESCRIPTION OF THE EMBODIMENT

The invention may provide a semiconductor device which allows formation of an element under an electrode pad and exhibits high reliability.

(1) According to one embodiment of the invention, there is provided a semiconductor device comprising:
a semiconductor layer;
an interlayer dielectric formed on the semiconductor layer;
a buffer layer formed on the interlayer dielectric; and
an electrode pad formed on the interlayer dielectric,
the buffer layer being formed to be covered by an edge portion of at least part of the electrode pad when viewed from a top side.

In the region near the edge of the electrode pad, stress occurs due to the electrode pad. Therefore, cracks tend to occur in the interlayer dielectric in the region near the edge of the electrode pad. For example, when a semiconductor element such as a MIS transistor has been formed in the region near the edge of the electrode pad, the characteristics of the MIS transistor may deteriorate. In the semiconductor device according to this embodiment, the above problem can be solved by forming the buffer layer to be covered by an edge portion of at least part of the electrode pad when viewed from the top side.

Moreover, since the stress can be reduced by forming the buffer layer, the mechanical strength of the interlayer dielectric under the electrode pad can be sufficiently increased. Therefore, an element formation region can be provided under the electrode pad, whereby a semiconductor device which is reduced in size due to an increase in the degree of integration of elements and exhibits improved reliability can be provided.

In the invention, the element formation region means a region in which various elements such as MIS transistors, diodes, and resistors are formed. In the invention, when a specific layer B is formed on (or above) a specific layer A, the layer B may be formed directly on the layer A, or another layer may be interposed between the layer B and the layer A.

The semiconductor device according to this embodiment may have the following features.

(2) In this semiconductor device,
the buffer layer may be formed in a predetermined region positioned outward from a line extending vertically downward from an edge portion of the electrode pad; and
an edge portion of the buffer layer may be covered by the edge portion of the electrode pad when viewed from the top side.

(3) In this semiconductor device,
the buffer layer may be formed in a predetermined region positioned outward and inward from a line extending vertically downward an edge portion of the electrode pad.

(4) In this semiconductor device, the buffer layer may have an enclosed shape.

(5) In this semiconductor device,
the buffer layer may be formed to be covered by a corner of the electrode pad when viewed from the top side.

(6) In this semiconductor device,
the electrode pad may have a rectangular shape having short sides and long sides; and
the buffer layer may be formed to be covered by an edge portion of one of the short sides of the electrode pad when viewed from the top side.

(7) In this semiconductor device, the buffer layer may include a metal layer.

(8) The semiconductor device may further comprise:
a passivation layer formed on the electrode pad and having an opening which exposes at least part of the electrode pad,
wherein the predetermined region positioned outward from a line vertically extending downward from the edge portion of the electrode pad has a width corresponding to a thickness of the passivation layer.

(9) The semiconductor device may further comprise a bump formed in the opening.

(10) In this semiconductor device,
an element may be formed on the semiconductor layer; and
the electrode pad may cover the element when viewed from the top side.

(11) In this semiconductor device, the element may be a transistor.

Some embodiments of the invention will be described below, with reference to the drawings.

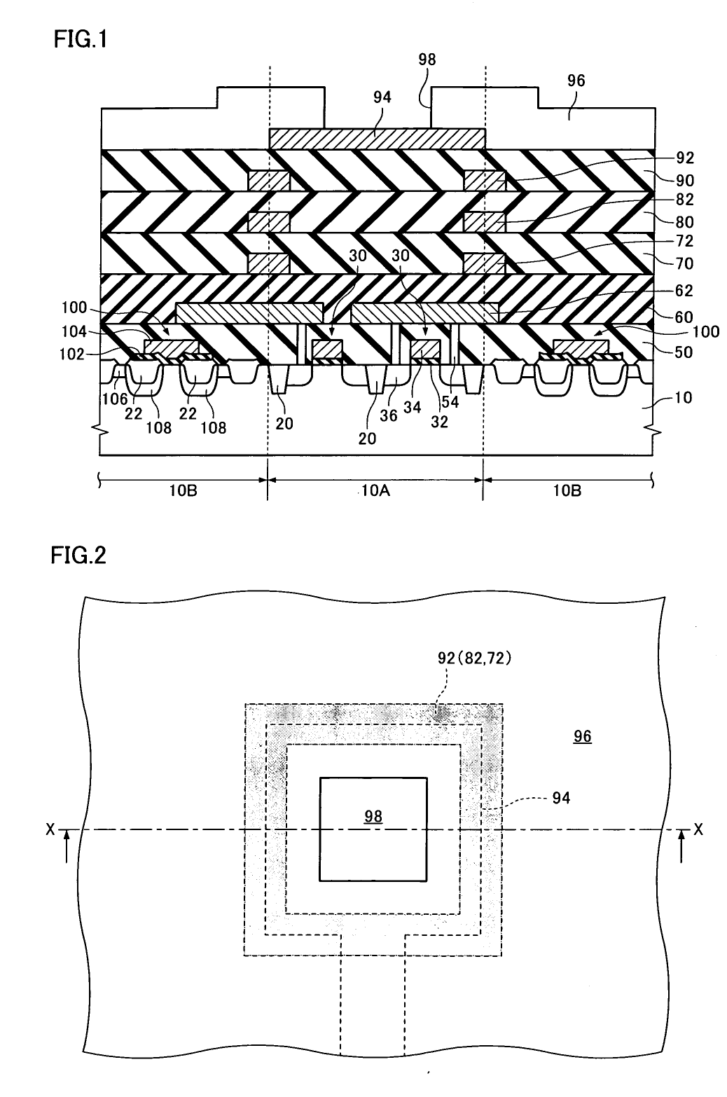

FIG. 1 is a cross-sectional view schematically showing a semiconductor device according to this embodiment, and FIG. 2 is a plan view schematically showing the relationship between an electrode pad and a buffer layer in the semiconductor device according to this embodiment. FIG. 1 shows the cross section along the line X-X shown in FIG. 2.

As shown in FIG. 1, the semiconductor device according to this embodiment includes a semiconductor layer 10. As the semiconductor layer 10, a single crystal silicon substrate, a silicon on insulator (SOI) substrate in which a semiconductor layer formed on an insulating layer is a silicon layer, a germanium layer, or a silicon germanium layer, or the like may be used.

An isolation insulating layer 20 is formed in the semiconductor layer 10. The isolation insulating layer 20 may be formed by a shallow trench isolation (STI) method, a local oxidation of silicon (LOCOS) method, or a semi-recessed LOCOS method. FIG. 1 shows the isolation insulating layer 20 formed by the STI method.

A first element formation region 10A is a region provided under an electrode pad 94. In the semiconductor device according to this embodiment, a second element formation region 10B is provided outside the first element formation region 10A.

A metal insulator semiconductor (MIS) transistor 30 is formed in the first element formation region 10A. The MIS transistor 30 includes a gate insulating layer 32, a gate electrode 34 formed on the gate insulating layer 32, and impurity regions 36 formed in the semiconductor layer 10. The impurity region 36 serves as a source region or a drain region. The gate electrode 34 includes a polysilicon layer or a polycide layer, for example. The MIS transistor 30 may include a sidewall insulating layer (not shown in FIG. 1).

A high-voltage MIS transistor 100 is formed in the second element formation region 10B. In more detail, the MIS transistor 100 having a LOCOS offset structure is formed in the second element formation region 10B. The MIS transistor 100 includes an offset insulating layer 22 which is formed in the semiconductor layer 10 and reduces an electric field, a gate insulating layer 102 formed on the semiconductor layer 10, a gate electrode 104 formed on part of the offset insulating layer 22 and the gate insulating layer 102, and impurity regions 106 formed in the semiconductor layer outside the gate electrode 104 and serving as a source region or a drain region. An offset impurity region 108 of the same conductivity type as that of the impurity region 106 and having an impurity concentration lower than that of the impurity region 106 is formed under the offset insulating layer 22.

In the MIS transistor 100, the ends (side surfaces) of the gate electrode 104 are positioned on the offset insulating layers 22. Therefore, the MIS transistor 100 causes the semiconductor layer 10 to be affected by stress to only a small extent in comparison with the MIS transistor 30 formed in the first element formation region 10A, whereby deterioration of the gate insulating layer 102 can be prevented.

The second element formation region 10B tends to be affected by stress which occurs due to the electrode pad 94. However, this problem can be solved by forming the MIS transistor 100 having the LOCOS offset structure and exhibiting a high mechanical strength in the second element formation region 10B, whereby the degree of integration of the MIS transistors can be increased.

A first interlayer dielectric 50, a second interlayer dielectric 60, a third interlayer dielectric 70, a fourth interlayer dielectric 80, and a fifth interlayer dielectric 90 are formed in that order on the MIS transistors 30 and 100. The interlayer dielectrics 50 to 90 may be formed using a known material. An interconnect layer 62 having a predetermined pattern is formed on the interlayer dielectric 50. The interconnect layer 62 and the impurity region 36 of the MIS transistor 30 are electrically connected through a contact layer 54. An interconnect layer (not shown) having a predetermined pattern is formed on each of the second to fifth interlayer dielectrics 60, 70, 80, and 90.

A first buffer layer 72 is formed on the second interlayer dielectric 60. A second buffer layer 82 is formed on the third interlayer dielectric 70. A third buffer layer 92 is formed on the fourth interlayer dielectric 80. Each of the first to third buffer layers 72, 82, and 92 includes a metal layer which is formed in the same step as the interconnect layer (not shown) formed in the same layer. A known metal such as aluminum or copper may be used as the material for the metal layer.

The electrode pad 94 having a rectangular planar shape is formed on the fifth interlayer dielectric 90. A passivation layer 96 is also formed on the fifth interlayer dielectric 90. An opening 98 which exposes at least part of the electrode pad 94 is formed in the passivation layer 96. As shown in FIGS. 1 and 2, the opening 98 may be formed to expose only the center region of the electrode pad 94. Specifically, the passivation layer 96 may be formed to cover the edge portion of the electrode pad 94. The passivation layer 96 may be formed of SiO₂, SiN, a polyimide resin, or the like. In the semiconductor device according to this embodiment, the term “electrode pad” refers to a region which includes a region in which the opening 98 is formed and has a width greater than that of the interconnect. A bump (not shown) may be formed in the opening 98.

The buffer layer is described below in detail.

In this embodiment, the buffer layer is formed to be covered by the edge portion of at least part of the electrode pad 94 when viewed from the top side.

In the example shown in the drawings, the first to third buffer layers 72, 82, and 92 are disposed under at least the outline of the electrode pad 94 when viewed from the top side. In this embodiment, the buffer layers 72, 82, and 92 have a rectangular enclosed planar shape, as shown in FIG. 2.

The buffer layers 72, 82, and 92 may be formed in a region including at least a region having a width corresponding to the thickness of the passivation layer 96 outward (in the direction opposite to the opening 98) from the edge of the electrode pad 94. For example, the above region may be a region having a width of 1.5 to 2.0 micrometers outward from the edge of the electrode pad 94. The reasons why the buffer layers are formed in such a region are as follows.

When the electrode pad 94 is formed, stress occurs in the interlayer dielectric at a position in which the edge of the electrode pad 94 is provided. When the bump (not shown) is formed on the electrode pad 94, continuous stress additionally occurs in the interlayer dielectric due to the internal stress of the bump. These stresses may cause cracks to occur in the interlayer dielectric at a position (edge of the electrode pad 94) in which the stresses occur. The cracks may reach the lowermost interlayer dielectric to affect the characteristics of the semiconductor element formed in such a region. For example, when a MIS transistor is formed in such a region, a gate insulating layer deteriorates, whereby a leakage current may be increased.

The passivation layer 96 is not formed on a surface of which the upper side has a uniform height. That is, the passivation layer 96 has a level difference corresponding to the shape of the electrode pad 94. For example, when mounting the semiconductor device using the chip-on-film (COF) technology, stress due to contact/bonding tends to be concentrated in the region in which the level difference is formed when connecting the bump with a connection line (lead wire) formed on a film. This also causes cracks to occur in the interlayer dielectric. The level difference generally occurs at a position located outward from the edge of the electrode pad 96 at a distance approximately corresponding to the thickness of the passivation layer 96. The formation region of the buffer layers 72, 82, and 92 may be specified taking the above-described problems into consideration. The buffer layer according to this embodiment may also be disposed inward from the edge of the electrode pad 94 continuously from the region outward from the edge of the electrode pad 94. Specifically, the buffer layer according to this embodiment may be formed in a region in which a problem such as cracks may occur due to the electrode pad 94.

According to this embodiment, the above-described problems can be solved by forming the buffer layers 72, 82, and 92. Specifically, when disposing the buffer layers 72, 82, and 92 at a predetermined position under the electrode pad 94, the buffer layers 72, 82, and 92 absorb the stress due to the electrode pad 94 and the bump or the stress which occurs when connecting the bump with the connection line or the like, whereby a problem such as occurrence of cracks in the interlayer dielectric can be prevented. Since the buffer layers 72, 82, and 92 include the metal layer to exhibit tenacity, the buffer layers 72, 82, and 92 reduce the stress to a large extent. Therefore, the element formation region 10A can be provided under the electrode pad 94. Since the semiconductor elements such as the MIS transistor can be formed in the element formation region 10A, the degree of integration of the elements can be increased.

According to this embodiment, since the buffer layers 72, 82, and 92 have an enclosed shape and are open at the center, the buffer layers 72, 82, and 92 have the following advantages in comparison with a plate-shaped buffer layer which does not have an opening.
(a) Since the interconnect layers can be formed inside the buffer layers 72, 82, and 92, the degrees of freedom of the interconnect design can be increased.
(b) When removing gas from the interlayer dielectric by heating, the gas can be discharged through the opening to ensure sufficient gas removal.
(c) The buffer layers 72, 82, and 92 do not hinder hydrogen sintering for recovering the crystallinity of the silicon substrate or the like by removing electric charges injected into the interlayer dielectric by sputtering or the like.
(d) Since the buffer layer can be provided in a small area, stress caused by the buffer layer can be reduced.

As described above, in the semiconductor device according to this embodiment, the semiconductor layer positioned under the electrode pad 94 is the element formation region 10A, and the buffer layers 72, 82, and 92 are formed in a predetermined region under the electrode pad 94. The stress caused by the electrode pad 94 and the bump can be reduced by providing the buffer layers 72, 82, and 92, and the degree of integration can be increased by disposing the semiconductor elements or the like under the electrode pad 94, whereby a semiconductor device which can be reduced in size and exhibits reliability can be provided.

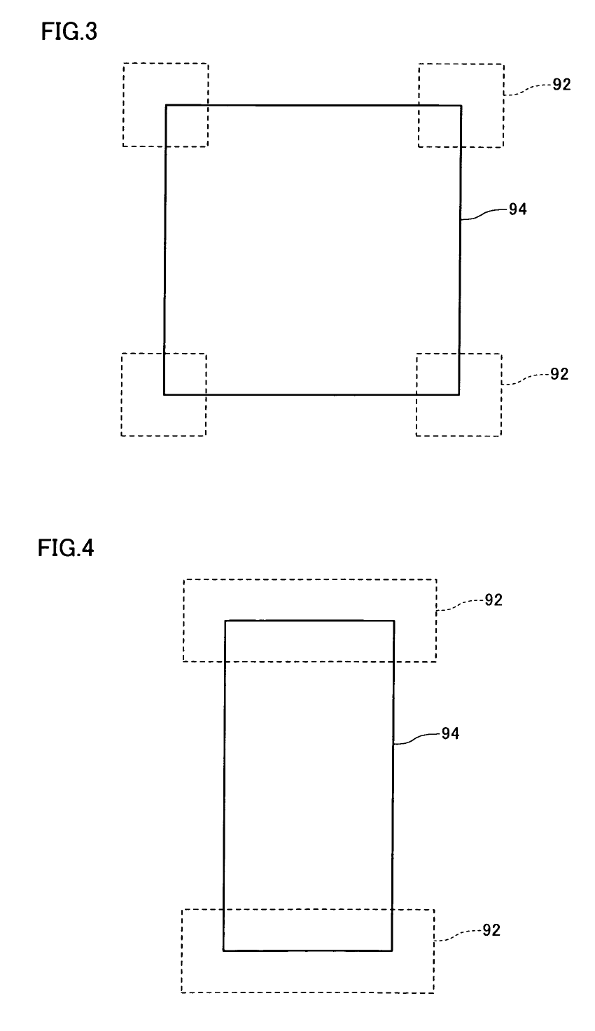

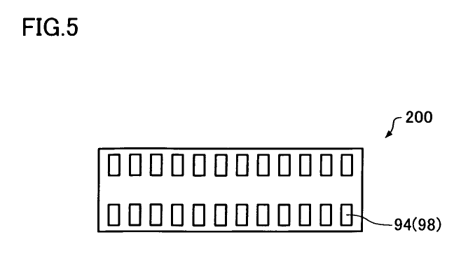

Modifications of the buffer layer according to this embodiment are described below with reference to FIGS. 3 and 4. FIGS. 3 and 4 are plan views schematically showing the shape and the arrangement of the electrode pad 94 and the buffer layer 92. In the examples shown in FIGS. 3 and 4, the buffer layer 92 is partially disposed along the outline (edge) of the electrode pad 94.

In a first modification shown in FIG. 3, the buffer layers 92 are disposed at the corners (four corners) of the electrode pad 94. When the electrode pad 94 is rectangular, stress concentration tends to occur at the four corners of the electrode pad 94. Therefore, the stress can be effectively reduced using a buffer layer having a small area by providing the buffer layers 92 at the four corners of the electrode pad 94.

In a second modification shown in FIG. 4, the electrode pad 94 is rectangular, and the buffer layers 92 are disposed along the short sides of the electrode pad 94. This modification has the following advantage when mounting the semiconductor device using the tape automated bonding (TAB) technology provided that a connection line (lead wire) formed on a film made of a polyimide resin or the like extends in the direction along the long side of the electrode pad 94. Specifically, the electrode pad 94 is pulled in the direction in which the connection line extends, whereby stress occurs on the short side of the electrode pad 94. Therefore, cracks tend to occur in the interlayer dielectric at the edge of the short side of the electrode pad 94. This modification reliably reduces the stress in a region in which the reliability tends to be decreased by providing the buffer layer 92 on the short side of the electrode pad 94.

As shown in FIG. 5, a semiconductor chip 200 which is reduced in size may be required to have a structure in which the electrode pad 94, the opening 98, and the bump (not shown) are formed to have a rectangular planar shape to provide a number of openings 98. According to this modification, a semiconductor device which is reduced in size and exhibits improved reliability can be provided by forming the buffer layer 92 in an appropriate region, even if the semiconductor device has such rectangular electrode pads 94 (bumps).

The above embodiments illustrate an example in which the semiconductor device includes five interlayer dielectrics and five interconnect layers. Note that the number of interlayer dielectrics and the number of interconnect layers are not limited thereto. A structure may also be employed in which three or more interlayer dielectrics are stacked and interconnect layers are provided in a number corresponding to the number of interlayer dielectrics. The buffer layer may be formed corresponding to each interconnect layer. Note that only one buffer layer may be formed, or the buffer layers may be formed corresponding to selected interconnect layers. It is preferable that the buffer layer be formed at a position close to the electrode pad from the viewpoint of reducing stress.

The invention is not limited to the above-described embodiments, and various modifications can be made. For example, the invention includes various other configurations substantially the same as the configurations described in the embodiments (in function, method and result, or in objective and result, for example). The invention also includes a configuration in which an unsubstantial portion in the described embodiments is replaced. The invention also includes a configuration having the same effects as the configurations described in the embodiments, or a configuration able to achieve the same objective. Further, the invention includes a configuration in which a publicly known technique is added to the configurations in the embodiments.

Although only some embodiments of the invention have been described in detail above, those skilled in the art will readily appreciate that many modifications are possible in the embodiments without departing from the novel teachings and advantages of this invention. Accordingly, all such modifications are intended to be included within the scope of this invention.

What is claimed is:

1. A semiconductor device comprising:
a semiconductor layer;
an interlayer dielectric formed on the semiconductor layer;
a buffer layer formed on the interlayer dielectric; and
an electrode pad formed on the interlayer dielectric,
the buffer layer being formed to be covered by an edge portion of at least part of the electrode pad when viewed from a top side.

2. The semiconductor device as defined in claim 1,
wherein the buffer layer is formed in a predetermined region positioned outward from a line extending vertically downward from an edge portion of the electrode pad; and
wherein an edge portion of the buffer layer is covered by the edge portion of the electrode pad when viewed from the top side.

3. The semiconductor device as defined in claim 1,
wherein the buffer layer is formed in a predetermined region positioned outward and inward from a line extending vertically downward an edge portion of the electrode pad.

4. The semiconductor device as defined in claim 2,
wherein the buffer layer has an enclosed shape.

5. The semiconductor device as defined in claim 1,
wherein the buffer layer is formed to be covered by a corner of the electrode pad when viewed from the top side.

6. The semiconductor device as defined in claim 2,
wherein the electrode pad has a rectangular shape having short sides and long sides; and
wherein the buffer layer is formed to be covered by an edge portion of one of the short sides of the electrode pad when viewed from the top side.

7. The semiconductor device as defined in claim 1, wherein the buffer layer includes a metal layer.

8. The semiconductor device as defined in claim 2, further comprising:
a passivation layer formed on the electrode pad and having an opening which exposes at least part of the electrode pad,
wherein the predetermined region positioned outward from a line vertically extending downward from the edge portion of the electrode pad has a width corresponding to a thickness of the passivation layer.

9. The semiconductor device as defined in claim 8, further comprising a bump formed in the opening.

10. The semiconductor device as defined in claim 1,
wherein an element is formed on the semiconductor layer; and
wherein the electrode pad covers the element when viewed from the top side.

11. The semiconductor device as defined in claim 10, wherein the element is a transistor.
